(19) United States
(12) Patent Application Publication
(10) Pub. No.: US 2010/0001211 A1
(43) Pub. Date: Jan. 7, 2010

(54) Method and apparatus for enhancing detection characteristics of a chemical sensor system

(75) Inventors: Weijie Huang, Monrovia, CA (US); Eve F. Fabrizio, Bay Village, OH (US); Timothy E. Burch, San Gabriel, CA (US)

Correspondence Address: FOLEY AND LARDNER LLP;SUITE 500, 3000 K STREET NW, WASHINGTON, DC, 20007, US

(73) Assignee: Smiths Detection Inc.

(21) Appl. No.: 12/216,223

(22) Filed: Jul. 1, 2008

(51) Int. Cl. G01N 37/00; G01R 35/00

(52) U.S. Cl. 250/492.1

(57) ABSTRACT

A method and apparatus for increasing detection characteristics of a chemical sensor array that has been previously exposed to an agent in order to detect and categorize the agent. Ultraviolet light at a predetermined wavelength is applied to the chemical sensor array, in order to desorb the agent from the chemical sensor array, so as to increase a resistance of the chemical sensor array. Alternatively or together with the ultraviolet light, a bias voltage is applied to at least one biasing electrode making up the chemical sensor array, in order to desorb the agent from the chemical sensor array, so as to increase the resistance of the chemical sensor array. The chemical sensor array may be a carbon nanotube sensor array.

### FIELD OF THE INVENTION

This invention is related in general to the field of chemical sensors, and in particular to enhancing detection characteristics of chemical sensors.

### BACKGROUND OF THE INVENTION

Sensor array units having sensor arrays are becoming very useful in today's society, with the threat of chemi- and bio-terrorism being more and more prominent. In more detail, chemical and biological warfare pose both physical and psychological threats to military and civilian forces, as well as to civilian populations.

An important feature of a sensor array unit is the ability to detect abnormalities in a sample, and to output an alarm when the abnormality is detected. Given that an abnormality may occur when only a very small concentration of a particular analyte exists in a sample, it is important that the sensor array unit is highly sensitive to such a very small concentration of the particular analyte.

As a result of multiple uses of a sensor array unit, drift as well as loss in sensor response occurs, whereby it is believed that such loss in sensor response is due to irreversible physically-adsorbed and chemically-adsorbed agents.

### SUMMARY OF THE INVENTION

The present invention relates to a method and apparatus for improving sensor array detection performance.

In accordance with one aspect of the invention, there is provided a method for increasing detection characteristics of a chemical sensor array that has been previously exposed to an agent in order to detect and categorize the agent. The method includes a step of applying ultraviolet light at a predetermined wavelength to the chemical sensor array, in order to desorb the agent from the chemical sensor array, so as to reset (or recover, or modulate, or modify, etc.) a resistance, conductance, capacitance, surface chemistry, and/or surface adsorbed species of the chemical sensor array.

In accordance with another aspect of the invention, there is provided a method for improving detection characteristics of a chemical sensor array that has been previously exposed to an agent in order to detect and categorize the agent, wherein the chemical sensor array includes at least one biasing electrode. The method includes the step of applying a bias to the at least one biasing electrode, in order to desorb the agent from the chemical sensor array, so as to reset (or recover, or modulate, or modify, etc.) resistance, conductance, capacitance, surface chemistry, and/or surface adsorbed species, of the chemical sensor array.

In accordance with another aspect of the invention, there is provided an apparatus for improving detection characteristics of a chemical sensor array that has been previously exposed to an agent in order to detect and categorize the agent. The apparatus includes an ultraviolet light emitting unit that emits ultraviolet light at a predetermined wavelength to the chemical sensor array, in order to desorb the agent from the chemical sensor array, so as to reset (or recover, or modulate, or modify, etc.) a resistance, conductance, capacitance, surface chemistry, and/or surface adsorbed species of the chemical sensor array.

In accordance with yet another aspect of the invention, there is provided a computer readable medium embodying computer program product for improving sensor response characteristics, the computer program product, when executed by a computer or a microprocessor, causing the computer or the microprocessor to perform the step of providing control signals to a light applying unit so as to apply ultraviolet light at a predetermined wavelength to the chemical sensor array, in order to desorb the agent from the chemical sensor array, so as to reset (or recover, or modulate, or modify, etc.) a resistance, capacitance, surface chemistry, and/or surface adsorbed species of the chemical sensor array.

In accordance with still another aspect of the invention that is provided a computer readable medium embodying computer program product for improving sensor response characteristics, the computer program product, when executed by a computer or a microprocessor, causing the computer or the microprocessor to perform the steps of applying a bias voltage to at least one biasing electrode of a chemical sensor array, in order to desorb the agent from the chemical sensor array, so as to reset (or recover, or modulate, or modify, etc.) a resistance, conductance, capacitance, surface chemistry, and/or surface adsorbed species of the chemical sensor array.

It is to be understood that both the foregoing general description and the following detailed description are exemplary and explanatory only and are not restrictive of the invention as claimed.

### BRIEF DESCRIPTION OF THE DRAWINGS

The accompanying drawings, which are incorporated in and constitute a part of this specification, illustrate several embodiments of the invention and, together with the description, serve to explain the principles of the invention.

FIG. 1 is a plot showing changes in electrical characteristics of a pristine SWNT film sample during cycles of NO₂ adsorption and photo induced desorption.

FIG. 2A shows the resistance of chemically modified CNT sensors in cycles of NO₂ exposure (−) and air purge, both without and with photo irradiation, in accordance with a first embodiment of the invention.

FIG. 2B is a plot showing a typical CNT response to NO₂ when no UV light is applied to the CNT sensor between exposures to NO₂.

FIG. 3 is a plot showing improvement of description time of NH₃ induced by a positive bias pulse applied by gate biasing

FIG. 4 is a plot of sensor response under applied gate pulses in the presence of ammonia concentration (75 ppm).

FIG. 5 is a plot of sensor response under applied bias pulses in the presence of NO₂ (300 ppb).

FIG. 6 shows a bias electrode, a counter electrode for bias, and sensing electrodes for a CNT FET according to the first embodiment of the invention.

FIG. 7 shows a gate being biased positive (+) for a CNT FET according to the first embodiment of the invention.

FIG. 8 is a block diagram of an apparatus for improving sensor detection characteristics of a carbon nanotube sensor array, according to the first embodiment of the invention.

FIG. 9A is a plot showing a typical baseline response of a CNT film to Cl₂, with baseline drift downward

FIG. 9B is a plot showing a response of a CNT film to Cl₂ when UV light is applied to the CNT film during air purge periods, in accordance with an embodiment of the present invention.

FIG. 10A is a diagram showing a perspective view of an apparatus for implementing photo-excitation to a chemiresistor electrode array, according to an embodiment of the present invention.

FIG. 10B is a diagram showing a side view of the apparatus shown in FIG. 10A.

FIG. 10C shows one possible implementation of a light providing unit to a sensor array, according to an embodiment of the present invention.

### DETAILED DESCRIPTION

Reference will now be made in detail to embodiments of the invention, examples of which are illustrated in the accompanying drawings. An effort has been made to use the same reference numbers throughout the drawings to refer to the same or like parts.

Unless explicitly stated otherwise, “and” can mean “or,” and “or” can mean “and.” For example, if a feature is described as having A, B, or C, the feature can have A, B, and C, or any combination of A, B. and C. Similarly, if a feature is described as having A, B, and C, the feature can have only one or two of A, B, or C.

Unless explicitly stated otherwise, “a” and “an” can mean “one or more than one.” For example, if a device is described as having a feature X, the device may have one or more of feature X.

A first embodiment of the present invention utilizes heat, light and potential bias in order to influence the adsorption or desorption of chemical agents with respect to a sensor array, in order to enhance the detection characteristics of the sensor array.

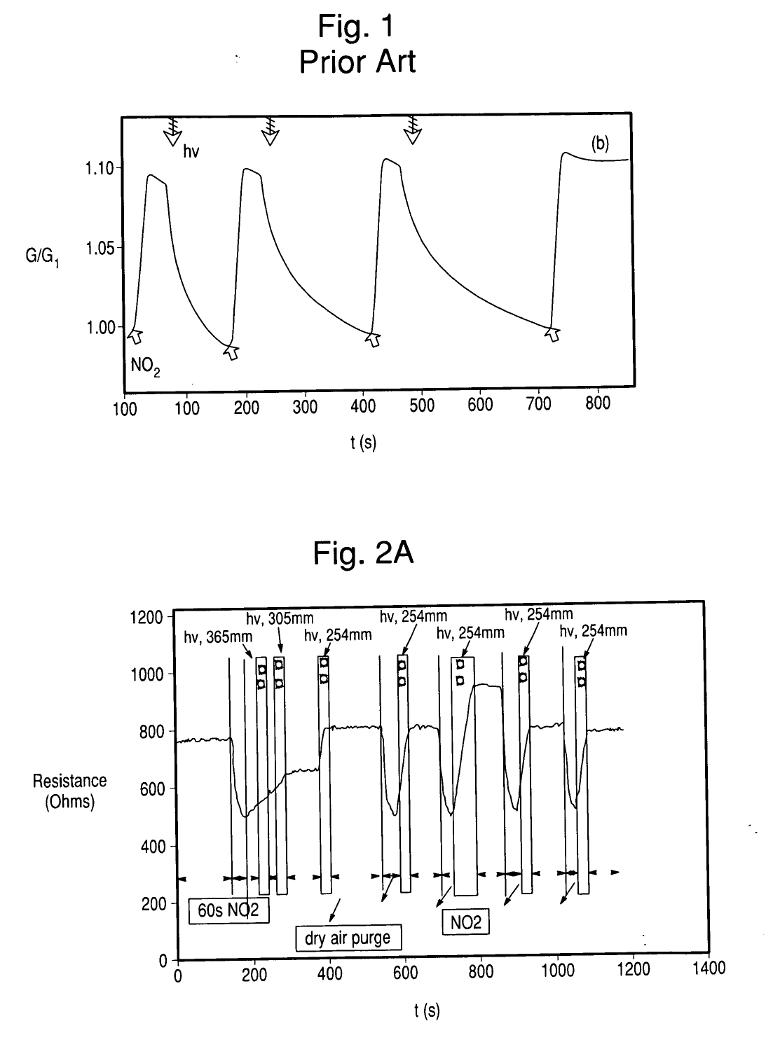

Molecular photodesorption can drastically alter the electrical characteristics of a single semiconducting SWNT (single walled carbon nanotube) sensor. Additionally, photodesorption phenomena have been observed with an SWNT film that includes mixed metallic and semiconducting nanotubes when exposed to high energy wavelengths. FIG. 1 is a plot that shows the effect of UV (ultraviolet light) illumination on a pristine SWNT film during cycles of NO₂ adsorption and desorption, whereby application of UV light increases the resistance (and thus enhances the detection characteristics) of the SWNT film.

Based on the above observation, the first embodiment uses photo irradiation for CNT sensors to increase or improve their sensitivity, whereby the photo irradiation can be used alone or together with heat treatment of the SWNT sensors that also increases their detection characteristics. Compared to heat treatments that take a longer period of time, photo irradiation provides for a faster, non-thermal treatment method chemical sensors, whereby the light treatment can be performed in periods of seconds to minutes instead of hours to days as needed for heat treatment of such sensors.

In more detail, the first embodiment provides for photo irradiation of functionalized SWNT resistors (or sensors) using, for example, millimeter sized UV LEDS (light emitting diodes), so as to reduce both baseline drift and response drift issues for the SWNT resistors due to irreversible adsorption of chemical agents onto the SWNT resistors. The results obtained by the inventors of this application, with respect to photodesorption using a UV lamp for CNT sensors that have been previously exposed to Cl₂, show marked improvement in the sensor detection characteristics. For example, results obtained from regenerating CNT sensors demonstrate photo irradiation from UV wavelength to near visible light is effective for regenerating the response characteristics of the CNT sensors back to their original, baseline response values (e.g., the response value prior to a first use of a CNT sensor). The regeneration of the baseline response in accordance with the first embodiment results in a resetting, recovery, and/or modulation of the resistance, conductance, capacitance, surface chemistry, and/or surface adsorbed species of the chemical sensor array.

When CNT sensors are exposed to an agent, there are two types of adsorption that may occur between the sensors and the agent, physi-sorption and chemisorption. When the CNT sensors are no longer exposed to the agent, the physisorbed agent usually will be released because there is no sharing of electrons between the surface of the CNT sensors and the agent. However, there is a sharing of electrons between the CNT sensors and the agent for the chemisorbed materials, and so they will not be released. The inventors of this application have determined that when an agent is chemisorbed to the surface of a sensor such as an CNT sensor, there needs to be provided a perturbation in the electron density between the agent and the CNT sensor in order to have the agent released from the CNT sensor. In the first embodiment, light, heat and voltage bias are used to release the agent from the surface of the CNT sensor so that the CNT sensor can be brought back to its initial state (or very close to that state) prior to being exposed to another agent.

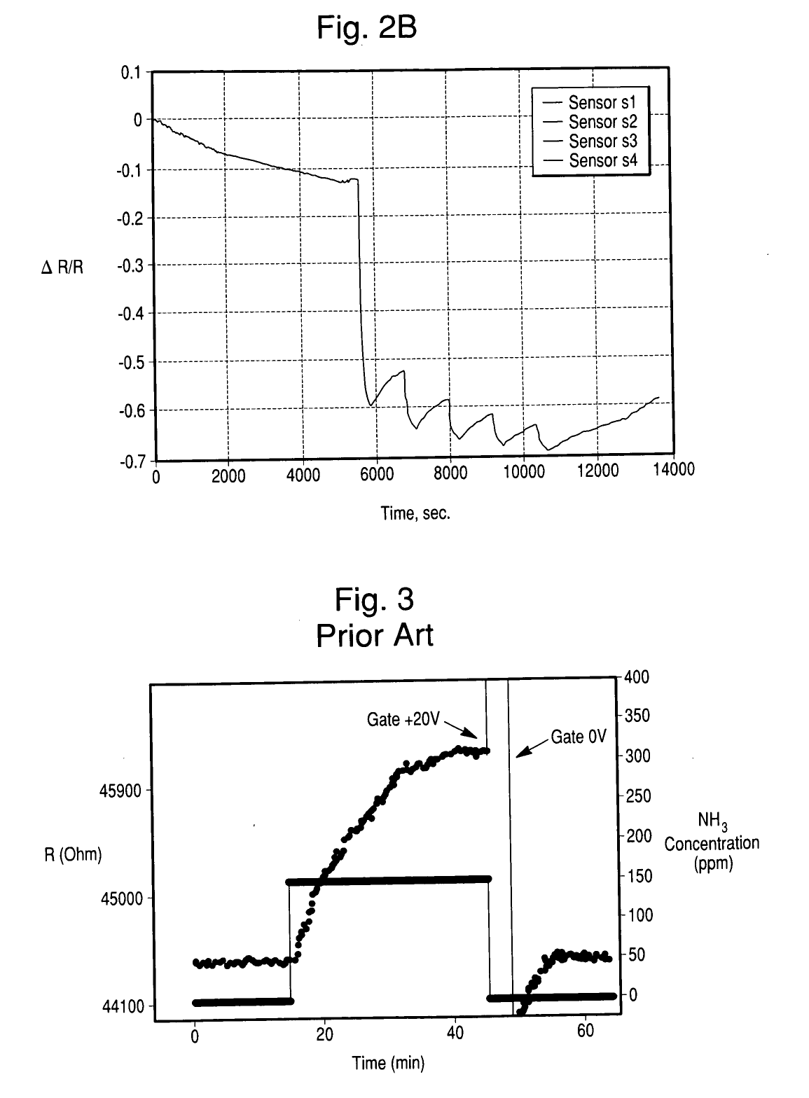

FIG. 2A shows the resistance of chemically functionalized carbon nanotube sensors in cycles of NO₂ exposure (−) and air purge, both without and with photo irradiation, whereby photo irradiation was performed using 254 nm light (periodically between time=300 and time=1000 seconds, and also at time=3600 seconds), 302 nm light (periodically between time=1400 and time=2700 seconds, and also at time=3400 seconds), and 365 nm light (at time=3200 to 3300 seconds). Each of those different UV light irradiations resulted in improvement of the resistance (and thus the detection characteristics) of the CNT sensors.

The purge (which can alternatively use nitrogen instead of air) is usually done as a fifteen minute exposure of the sensor array to nitrogen or air, which follows a two to five minute exposure of the sensor array to the agent to be detected. The purge times are shown in FIG. 2A by way of the dotted lines at the bottom of the plot. During the exposure to the nitrogen or air, the agent should diffuse out of the material making up the sensor array, to thereby result in a change of the resistance of the sensor array back to its baseline value. However, for certain sensor arrays such as CNTs, while some of the agent is removed during the nitrogen or air purge, some of the agent remains adhered to the sensor array. The present invention provides a technique to remove all or a large percentage of that remaining portion of the agent from the sensor array.

As the results shown in FIG. 2A indicate, photoexcitation stimulates CNT-agent interface states and likely causes molecular desorption from the surface of the carbon nanotubes that correspond to the CNT sensors, either through the injection of electrons or holes into the molecules and/or CNTs. The inventors have postulated that similar results can also be obtained (or enhanced) by directly injecting electrons or holes directly into the CNTs making up a CNT film of a carbon nanotube sensor by applying a potential that biases the CNT film.

FIG. 2B shows a typical CNT response to NO₂ when no UV light is applied to the CNT sensor between exposures to NO₂, and whereby the downward baseline drift in resistance can clearly be seen in this figure. This downward baseline drift results in decreased effectiveness of the CNT sensor.

Chemical sensing in a carbon nanotube (CNT) film may take place through a number of different mechanisms, whereby adsorption of chemical analytes on or near the CNT film may change the charge carrier mobility, CNT-electrode contact resistance, CNT-CNT contact resistance, gate capacitance, or charge density (through charge transfer, or doping).

In more detail, gating voltage applied to CNT films set up similar to field effect transistors (FETs) can effectively remove irreversibly adsorbed agents. This effect for FETs is described, for example, in the following references: a) “Optimization of NOx gas sensor based on single walled carbon nanotubes”, Sensors Actuators B., 2006, 118, 226-231 by Lucci, M., Realle, A., Di Carlo, A.; Orlanducci, S.; Tamburri, E.; Terranova, M. L.; Davoli, I.; Di Natale, C.; Amico, A. D.; and Paolesse, R.; and b) Carbon nanotubes for gas detection: materials preparation and device assembly”, J. Phys.: Condens. Matter, 2007, 225004-225018 by Terranova, M. L.; Lucci, M.; Orlanducci, S.; Tamburri, E.; Sessu V.; Reale, A.; and Di Carlo A. However, because this is a capacitive effect, the gating voltages applied in carbon nanotube field effect transistor films (CNT-FETs) are relatively high. The inventors of this application have determined that by biasing electrodes in direct contact with the CNT film, a potential would be applied across the electrodes, thereby changing the energy levels within the CNT film. In one particular implementation of the first embodiment, forcing the CNT film to be p-doped leads to the desorption of electron withdrawing agents such as nitrogen dioxide (NO₂), and then forcing the CNT film to be n-doped results in the desorption of electron donating groups such as ammonia (NH₃).

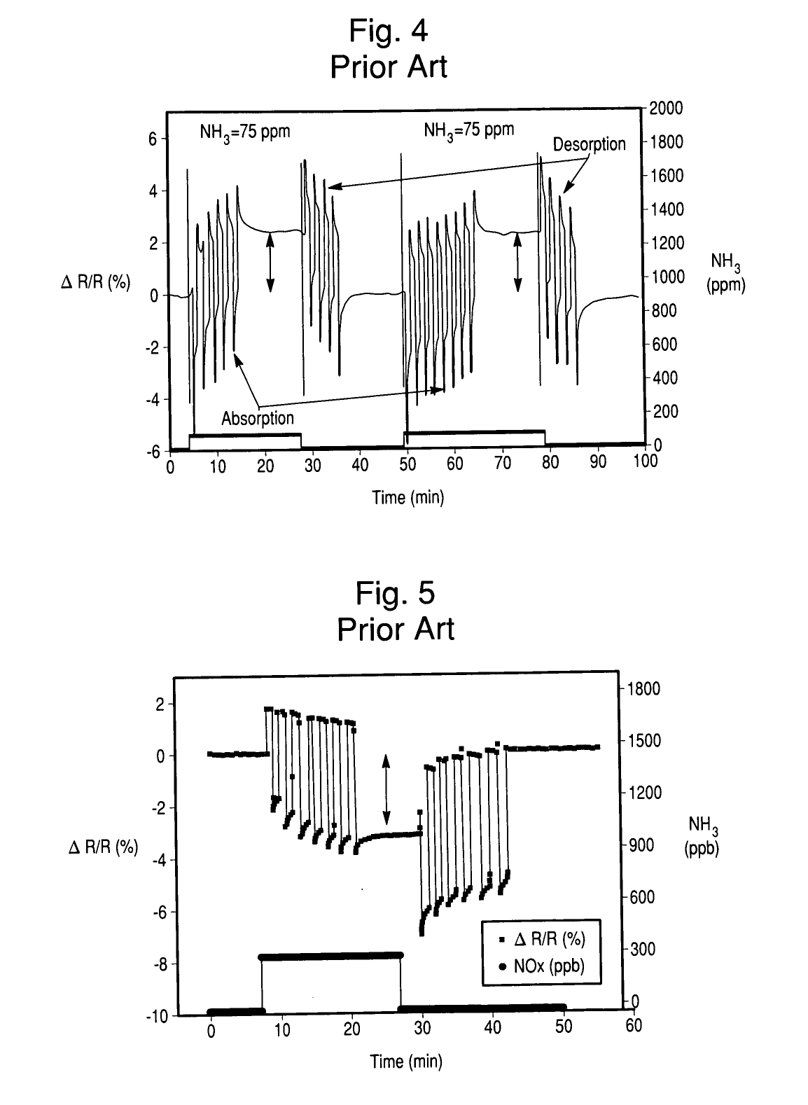

FIGS. 3, 4 and 5 show improved sensor characteristics for ammonia response and nitrogen dioxide response that have been obtained using voltage gating signals applied to a FET. In those figures, the resistance of the FET increases due to the application of gating pulses in an indirect manner to the FETs. If such FETs are to be included as a part of a CNT film of a chemical sensor, the inventors of this application have determined that providing gating pulses directly to the FETs would cause desorption of the ammonia and the nitrogen dioxide adhered to the CNT film, to thereby increase the detection characteristics for future detections of agents. In more detail, FIG. 3 is a plot showing improvement of description time of NH₃ induced by a positive gate pulse applied by gate biasing. FIG. 3 is obtained from “Optimization of NOx gas sensor based on single walled carbon nanotubes”, Sensors Actuators B., 2006, 118, 226-231 by Lucci, M., Realle, A., Di Carlo, A.; Orlanducci, S.; Tamburri, E.; Terranova, M. L.; Davoli, I.; Di Natale, C.; Amico, A. D.; and Paolesse, R. FIG. 4 is a plot of sensor response under applied gate pulses in the presence of ammonia concentration (75 ppm). FIG. 5 is a plot showing improvement of sensor response based on applied gate pulses in the presence of NO₂ concentration (300 ppb). By applying bias by way of step potential pulses provided directly to a CNT film, the inventors of this application have determined that even better detector response characteristics can be obtained than based solely on using gate pulsing of FETs as shown in FIGS. 3, 4 and 5. FIGS. 4 and 5 are obtained from “Carbon nanotubes for gas detection: materials preparation and device assembly”, J. Phys.: Condens. Matter, 2007, 225004-225018 by Terranova, M. L.; Lucci, M.; Orlanducci, S.; Tamburri, E.; Sessu V.; Reale, A.; and Di Carlo A.

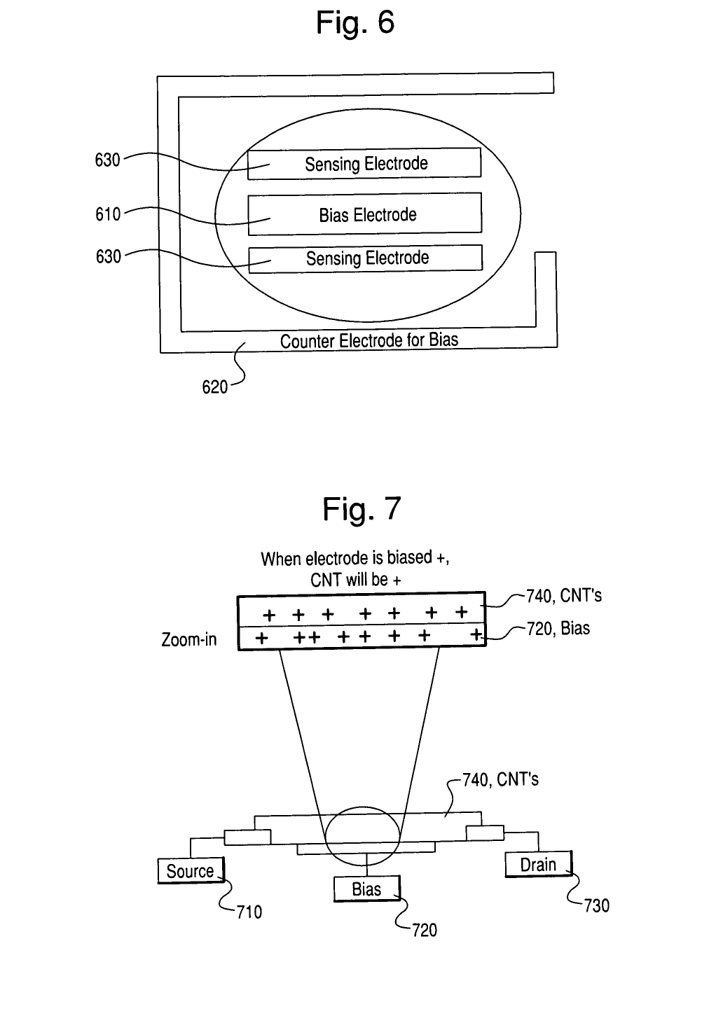

FIGS. 6 and 7 shows potential electrode designs for direct biasing of CNT films, which may be utilized to provide the bias signals directly to the CNTs, in accordance with the first embodiment. FIG. 6 shows a bias electrode 610, a counter electrode for the bias electrode 620, and two sensing electrodes 630 that together make up a CNT sensor system. FIG. 7 shows that when a positive potential is applied to the bias electrode 720 the CNT film 740 will become positive (+), and whereby the sensing electrodes, a source 710 and drain 730 make up a portion of the CNT sensor film 740. With the CNT film (740) positive in potential, electron withdrawing agents such as nitrogen dioxide and chlorine will be removed while electron donating agents such as ammonia will be more strongly adsorbed. Similar to what is shown in FIG. 7, the bias electrode 720 can also be biased negative (“−”), to remove electron donating agents while adsorbing electron withdrawing agents from the CNT film 740. By directly providing voltage bias to the CNT film 740, adsorption and desorption rates of agents with respect to the CNT film 740 can be controlled to enhance both agent detection limits and selectivity.

Additionally, heat treatment has been applied by the inventors in CNT film pre-treatment in an HCl test. The results obtained show that thermal desorption under vacuum accelerated molecular desorption in the case of an HCl test resulted in increased baseline recovery. Thus, heat treatment and light treatment and bias treatment on CNT sensor films to respond to agent exposures as both pre- and post-treatment steps provide for enhanced sensor detection characteristics for carbon nanotube (or CNT) sensors, and can be applied in an alternative implementation of the first embodiment. Also, heat can be precisely controlled with fast response times using microfabricated heaters positioned directly under each of the sensing elements.

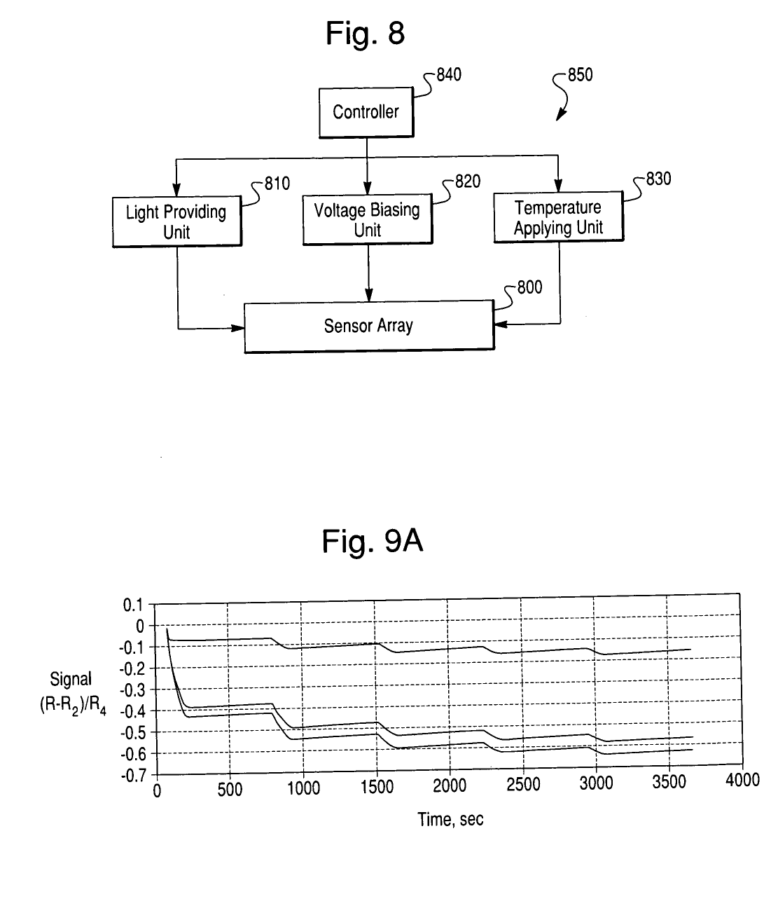

FIG. 8 is a block diagram of a sensor detection improvement apparatus 850 according to the first embodiment. A light providing unit 810 provides light at one or more predetermined wavelengths to a carbon nanotube sensor array 800. A voltage biasing unit 820 provides gate voltage pulses to a gate electrode of one or more FETS making up a portion of the carbon nanotube sensor array 800. A temperature applying unit 830 applies heat to the carbon nanotube sensor array 800. A controller 840 provides control signals to the light providing unit 810, the voltage biasing unit 820, and the temperature applying unit 830, for enabling one or more of those elements to act on the array 800 so as to remove agent that has been previously adsorbed to the array 800.

The controller 840 is operated under operation of a computer program stored in a computer readable medium, and provides such signals based on information as to current detection characteristics of the array 800 as well as information as to previous uses of the array 800 (e.g., agents for which the array 800 was exposed to and when and for how long those exposures occurred). Logic code is preferably provided for the computer program executed by the controller 840 for determining the specific light wavelengths to apply to the array 800, the number and duration of gate pulses to apply to the array 800, and the temperature and duration of heat to apply to the array 800, whereby such logic code may be developed by previous experiments performed on similar types of test arrays. By the providing of one or more of light, gate voltage biasing and heat to the carbon nanotube sensor array 800, sensor detection characteristics of the carbon nanotube sensor array 800 are improved by removing agent that has been previously adsorbed to the array 800 from past uses of a sensor apparatus that includes the array 800.

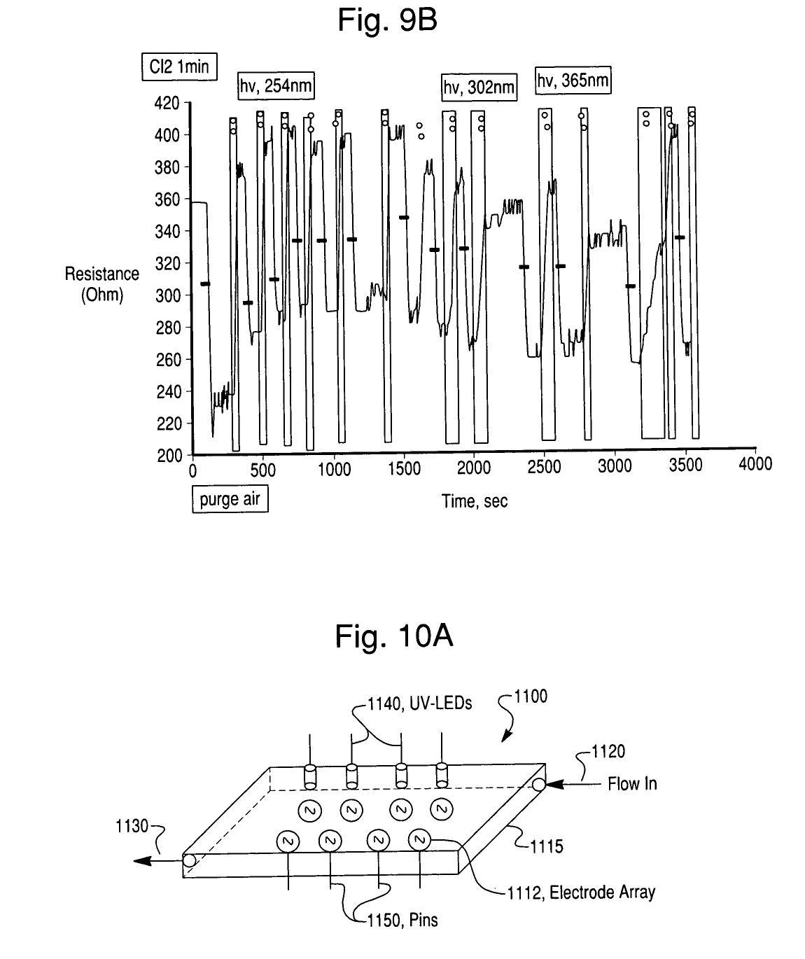

FIG. 9A shows a typical baseline response of a CNT film to Cl₂, with baseline drift downward. This downward drift in sensor response characteristics results in Cl₂ response of a sensor decreasing following a first exposure of the sensor, which is an undesirable characteristic of a sensor.

FIG. 9B shows a response of a CNT film to Cl₂ when UV light is applied to the CNT film during air purge periods, in accordance with an embodiment of the present invention. As can be seen in FIG. 9B, the downward drift of the sensor is removed, and the Cl₂ response characteristics are very consistent and strong for each exposure of the CNT film to a Cl₂ agent. The UV light used in FIG. 9B is primarily 254 nm light, whereby 365 nm light and 305 nm light is also used in the second and third light exposures of the CNT film. The return of the resistance of the CNT film back to its baseline resistance (around 800 ohms) results in a regeneration of a sensor array that includes one or more CNT films.

As discussed above, a return of the resistance of a CNT film back to its original, baseline resistance, by use of one or more or light, gate pulses, and heat, provides for a regeneration of the CNT film. In certain circumstances, such as when a CNT film is exposed to NH₃ and then an air purge in which UV light is provided to the CNT film, the resistance of the CNT film has been determined to actually increase over its baseline value, which results in non-consistent (and hence undesirable) detection results. Thus, for cases where a certain agent, such as NH₃, is detected by a sensor array made up of CNT film, techniques other than light should be performed, such as using potential pulse biasing and/or heat to regenerate the CNT film.

In a second embodiment of the invention, referring back to FIG. 8, the controller 840 has access to a memory (not shown, but it may be internal to the controller 840 or external to but directly accessible by the controller 840) to determine what type of regeneration to apply to a sensor that has been used to detect particular agents. Based on the types of agents previously detected by the sensor, and based on information stored in the memory as to the best type of regeneration techniques to apply to that sensor, one or more of a heat treatment, a light treatment, and a gate biasing treatment is used to reset the sensor back to its original response detection characteristics. The information stored in the memory would be based on experiments performed on different types of sensors that are exposed to different types of agents, whereby the improvements (or not) in sensor detection characteristics are obtained and analyzed.

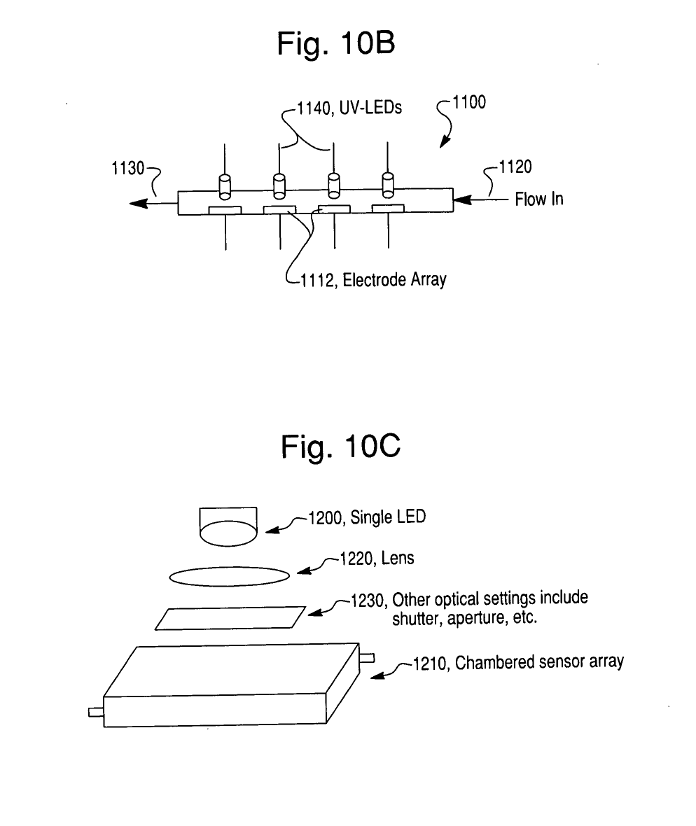

FIG. 10A is a diagram showing a perspective view of a system 1100 for implementing photo-excitation to a chemiresistor electrode array, according to a third embodiment of the invention, and FIG. 10B is a diagram showing a side view of the system 1100. The chemisensor electrode array 1112 is made up of a plurality of individual electrodes 1110, disposed in a matrix of sensors on a substrate 1115. A flow-in path 1120 for receiving an agent and purge gas is provided for the substrate 1115, and a flow-out path 1130 is also provided. A plurality of UV LEDs 1140 are provided on the substrate 1115, whereby the UV LEDs 1140 are provided on a one-to-one basis above the respective electrodes 1110 making up the chemisensor electrode array, whereby those UV LEDs 1140 are activated to “regenerate” the individual electrodes during an air purge period. Provided beneath each of the electrodes 1110 on the substrate 1115 on a one-to-one basis are pins 1150 that provide respective potential pulses to the bias electrodes 1110, in order to bias the CNT films so as to result in regeneration of the chemisensor electrode array. The application of potential pulses may be provided concurrently with the application of UV light, or separate therefrom, based on the type of agent previously exposed to the chemisensor electrode array and the type of electrodes making up the chemisensor electrode array. Not shown in FIGS. 10A and 10B is a heating element (or microfabricated heaters) that may also be provided on the substrate 1115 directly above or directly below each of the individual electrodes 1110, so as to regenerate the chemisensor electrode array by heating the respective electrodes during an air purge period.

FIG. 10C shows one possible implementation of a light providing unit for regenerating a sensor array, according to a fourth embodiment. In FIG. 10C, a single LED 1200 provides light at a specific wavelength to a chambered sensor array 1210, whereby a lens 1220 and other optical settings (e.g., shutter and/or aperture) 1230 are provided between the lens 1220 and the chambered sensor array 1210. The configuration shown in FIG. 10C allows using a single LED to illuminate (and thereby regenerate) an arrays of sensors, instead of requiring of a matrix of LEDs to perform that task.

The embodiments described above have been set forth herein for the purpose of illustration. This description, however, should not be deemed to be a limitation on the scope of the invention. Various modifications, adaptations, and alternatives may occur to one skilled in the art without departing from the claimed inventive concept. For example, while the embodiments have been described with respect to regenerating a carbon nanotube sensor array (CNT), they can be applied to different types of sensors, such as carbon black sensors, carbon black filled polymer composite sensors, or modified CNTs, whereby one or more of light treatment, heat treatment, and voltage biasing may be performed to regenerate those types of sensors. The spirit and scope of the invention are indicated by the following claims.

What is claimed is:

1. A method for improving detection characteristics of a chemical sensor array that has been previously exposed to an agent in order to detect and categorize the agent, the method comprising:
applying ultraviolet light at a predetermined wavelength to the chemical sensor array, in order to desorb the agent from the chemical sensor array, so as to return a resistance, conductance and/or capacitance of the chemical sensor array back to its original value.

2. The method according to claim 1, further comprising the step of:
applying heat to the chemical sensor array, in order to desorb the agent from the chemical sensor array, so as to return the resistance, conductance, and/or capacitance of the chemical sensor array back to its original value.

3. The method according to claim 1, wherein the chemical sensor array includes at least one biasing electrode, the method further comprising the step of:
applying a voltage to the at least one biasing electrode, in order to desorb the agent from the chemical sensor array, so as to return the resistance, conductance, and/or capacitance of the chemical sensor array back to its original value.

4. The method according to claim 3, wherein the chemical sensor array comprises a carbon nanotube sensor array that is either pristine or chemically-modified sensors, or both.

5. The method according to claim 3, wherein the applying step is performed periodically at predetermined intervals.

6. The method according to claim 2, wherein the chemical sensor array includes at least one biasing electrode, the method further comprising the step of:
applying a bias voltage to the at least one biasing electrode, in order to desorb the agent from the chemical sensor array, so as to return the resistance, conductance, and/or capacitance of the chemical sensor array back to its original value.

7. A method for improving detection characteristics of a chemical sensor array that has been previously exposed to an agent in order to detect and categorize the agent, wherein the chemical sensor array includes at least one biasing electrode, the method further comprising the step of:
applying a bias voltage to the at least one biasing electrode, in order to desorb the agent from the chemical sensor array, so as to return a resistance, conductance and/or capacitance of the chemical sensor array back to its original value.

8. The method according to claim 7, further comprising the step of:
applying ultraviolet light at a predetermined wavelength to the chemical sensor array, in order to desorb the agent from the chemical sensor array, so as to return a resistance, conductance and/or capacitance of the chemical sensor array back to its original value.

9. The method according to claim 7, further comprising the step of:
applying heat to the chemical sensor array, in order to desorb the agent from the chemical sensor array, so as to return the resistance, conductance and/or capacitance of the chemical sensor array back to its original value.

10. The method according to claim 7, wherein the chemical sensor array comprises a carbon nanotube sensor array that includes either pristine or chemically-modified sensors, or both.

11. The method according to claim 7, wherein the applying step is performed periodically at predetermined intervals.

12. An apparatus for improving detection characteristics of a chemical sensor array that has been previously exposed to an agent in order to detect and categorize the agent, the apparatus comprising:
an ultraviolet light emitting unit that emits ultraviolet light at a predetermined wavelength to the chemical sensor array, in order to desorb the agent from the chemical sensor array, so as to return a resistance, conductance and/or capacitance of the chemical sensor array back to its original value.

13. The apparatus according to claim 12, wherein the ultraviolet light emitting unit includes at least one light emitting diode.

14. The apparatus according to claim 12, wherein the chemical sensor array includes at least one biasing electrode, the apparatus further comprising:
a bias voltage applying unit configured to applying a bias voltage to the at least one biasing electrode, in order to desorb the agent from the chemical sensor array, so as to return the resistance, conductance and/or capacitance of the chemical sensor array back to its original value.

15. The apparatus according to claim 12, further comprising:
a heating unit configured to apply heat to the chemical sensor array, in order to desorb the agent from the chemical sensor array, so as to return the resistance, conductance and/or capacitance of the chemical sensor array back to its original value.

16. The apparatus according to claim 12, wherein the chemical sensor array comprises a carbon nanotube sensor array.

17. The apparatus according to claim 14, wherein the bias voltage applying unit applies the bias voltage periodically at predetermined intervals to the chemical sensor array.

18. A computer readable medium embodying computer program product for improving sensor response characteristics, the computer program product, when executed by a computer or a microprocessor, causing the computer or the microprocessor to perform the steps of:
providing control signals to a light applying unit so as to apply ultraviolet light at a predetermined wavelength to a chemical sensor array, in order to desorb the agent from the chemical sensor array, so as to return a resistance, conductance and/or capacitance of the chemical sensor array back to its original value.

19. The computer readable medium according to claim 18, wherein the light applying unit corresponds to at least one LED.

20. The computer readable medium according to claim 18, wherein the chemical sensor array is a carbon nanotube sensor array that includes either pristine or chemically-modified sensors, or both.

21. A computer readable medium embodying computer program product for improving sensor response characteristics, the computer program product, when executed by a computer or a microprocessor, causing the computer or the microprocessor to perform the steps of applying a bias voltage to at least one biasing electrode of a chemical sensor array, in order to desorb the agent from the chemical sensor array, so as to return a resistance, conductance and/or capacitance of the chemical sensor array back to its original value.

22. The computer readable medium according to claim 21, wherein the chemical sensor array is a carbon nanotube sensor array that includes either pristine or chemically-modified sensors, or both.

23. The computer readable medium according to claim 21, wherein the sensor array is a carbon black or carbon black filled polymer composite sensor array.
